(19) United States
(12) Patent Application Publication
(10) Pub. No.: US 2004/0095799 A1
(43) Pub. Date: May 20, 2004

(54) 2T2C signal margin test mode using different pre-charge levels for BL and/BL

(76) Inventors: Michael Jacob, Kanagawa-ken (JP); Thomas Roehr, Kanagawa-ken (JP); Joerg Wohlfahrt, Kanagawa-ken (JP); Hans-Oliver Joachim, Kanagawa-ken (JP)

Correspondence Address: FISH & RICHARDSON, PC, 12390 EL CAMINO REAL, SAN DIEGO, CA, 92130-2081, US

(21) Appl. No.: 10/301,547

(22) Filed: Nov. 20, 2002

(51) Int. Cl. G11C 11/22; G11C 11/24; G11C 29/00

(52) U.S. Cl. 365/149; 365/207; 365/201; 365/145

(57) ABSTRACT

The present invention provides a test mode section for facilitating a worst case product test sequence for signal margin to ensure full product functionality over the entire component lifetime taking all aging effects into account. A semiconductor memory test mode configuration includes a first capacitor for storing digital data The capacitor connects a cell plate line to a first bit line through a first select transistor. The first select transistor is activated through a connection to a word line. A second capacitor stores digital data and connects the cell plate line to a second bit line through a second select transistor. The second select transistor is also activated through a connection to the word line. A sense amplifier is connected to the first and second bit lines and measures a differential read signal on the first and second bit lines. A potential is connected to the first bit line through a third transistor and changes a pre-charge signal level on the first bit line when the third transistor is turned on to reduce the differential read signal.

### RELATED APPLICATIONS

The present disclosure is related to the following concurrently filed applications, all of which are to be assigned to Infineon Technologies AG and all of which are hereby incorporated by reference in their entirety into the present disclosure:

“2T2C Signal Margin Test Mode Using Resistive Element” to Michael Jacob et al., attorney reference number FP1783; “2T2C Signal Margin Test Mode Using a Defined Charge and Discharge of BL and /BL” to Hans-Oliver Joachim et al., attorney reference number FP1807; and “2T2C Signal Margin Test Mode Using a Defined Charge and Discharge of BL and /BL” to Hans-Oliver Joachim et al., attorney reference number FP1808.

### FIELD OF THE INVENTION

The present invention relates to the implementation of circuits for testing signal margin in memory cells operating in a 2T2C configuration.

### BACKGROUND OF THE INVENTION

In semiconductor memories, reliability issues have become more complicated with increasing memory sizes, smaller feature sizes and lower operating voltages. It has become more important to understand the cell signal sensing operation, the signal of memory cells and the limiting factors. One particularly important characteristic in reliability determinations of semiconductor memories is the signal margin. In a 2T2C memory cell configuration, the signal margin is a measure of the zero-versus-one signal measured by the sense amplifier It is particularly useful to be able to measure the signal margin at product level. The results of product-level signal-margin tests can be used to optimize reliability and as well as the sense amplifier design and the bit line architecture to optimize dynamic memory cell readout. Moreover, a product level test sequence for signal margin can help ensure full product functionality over the entire component lifetime taking all aging effects into account.

Among the more recent semiconductor memories, Ferroelectric Random Access Memories (FeRAMs) have attracted much attention due to their low-voltage and high-speed operation in addition to their non-volatility FIG. 1 shows a typical prior art FeRAM memory cell in a 2T2C configuration The 2T2C configuration utilizes two transistors and two capacitors per bit. The 2T2C configuration is beneficial because it allows for noise cancellation between the transistors. Two storage capacitors (Cferro) are connected to a common plate line (PL) on one side and to a pair of bit lines (BL, /BL) on the other side via two select transistors (TS). The two transistors are selected simultaneously by a common word line (WL). A dedicated bit line capacitance (CBL) is connected to each bit line. This bit line capacitance is required for the read operation of the memory cell. The differential read signal on the bit line pair is evaluated in a connected sense amplifier. The polarization is always maintained in directly opposed states in the two storage capacitors of one 2T2C memory configuration.

The signals on the bit lines during a read access are shown in FIG. 4. FIGS. 4-7 of the present disclosure all include a plot of the read signals on BL /BL vs. time. In these plots, one of the lines represents the read signal on BL and one represents the read signal on /BL. Which signal is represented by which of the lines depends on whether the read signal on BL or the read signal on /BL is larger. Both bit lines BL and /BL are pre-charged to the same level (e.g. 0V in the figure). Also, shortly before t0, the word line WL is activated (here “active” means WL is high for conventional FeRAMs and low for chain FeRAMs) The word line WL is not deactivated until shortly after write-back is finished. At time t0 the plate is activated and a read signal appears on the bit lines according to the capacitance ratio Cferro/CBL. The effective capacitance of a ferroelectric capacitor depends on its polarization state prior to the read operation. At time t1 the full read signals are developed on the two bit lines. At t2 the sense amplifier is activated and the bit line signals are boosted to the full bit line voltages. At t3 the sense amplifier is deactivated and the access cycle ends at t4.

A good solution for determining signal margin in FeRAM memory cells utilizing a single transistor and capacitor (1T1 C) is to sweep the reference bit line voltage. A prior art method for determining signal margin in 2T2C FeRAM memory cells is to shift the bit line level by capacitor coupling. However, this method is unsatisfactory because it requires an additional capacitor.

It would therefore be desirable to provide a circuit with a test mode section for facilitating a worst case product test sequence for signal margin. It would also be desirable to design such a circuit for use with semiconductor memories in a 2T2C configuration without requiring additional capacitors in the circuit.

### SUMMARY OF THE INVENTION

The present invention provides a test mode section for facilitating a worst case product test sequence for signal margin to ensure full product functionality over the entire component lifetime taking all aging effects into account. The invention works well with semiconductor memories having a 2T2C configuration.

A first aspect of the present invention proposes in general terms a test mode section for facilitating a worst case product test sequence for signal margin to ensure full product functionality over the entire component lifetime taking all aging effects into account. A semiconductor memory test mode configuration includes a first capacitor for storing digital data The capacitor connects a cell plate line to a first bit line through a first select transistor. The first select transistor is activated through a connection to a word line. A second capacitor stores digital data and connects the cell plate line to a second bit line through a second select transistor The second select transistor is also activated through a connection to the word line. A sense amplifier is connected to the first and second bit lines and measures a differential read signal on the first and second bit lines. A potential is connected to the first bit line through a third transistor and changes a pre-charge signal level on the first bit line when the third transistor is turned on to reduce the differential read signal.

Another aspect of the present invention includes a method for testing a semiconductor memory comprising the steps of identifying a first bit line that is to have a lower read signal than a second bit line; activating a third transistor connected to the first bit line for a time interval to pre-charge the first bit line to a potential level higher than a pre-charge potential level of the second bit line; activating a cell plate line to produce a read signal on the first and second bit lines representing digital data stored by a pair of capacitors connected to the cell plate line through first and second transistors; activating a sense amplifier connected to the first and second bit lines thereby boosting read signals on the first and second bit lines; and determining a reduced differential read signal on the first and second bit lines due to the increased pre-charge potential level on the first bit line.

### BRIEF DESCRIPTION OF THE FIGURES

Further preferred features of the invention will now be described for the sake of example only with reference to the following figures, in which:

FIG. 1 illustrates a 2T2C memory configuration of the prior art

FIG. 2 plots the signals on the bit lines during a read access cycle in the prior art circuit of FIG. 1.

FIG. 3 shows a memory configuration of the present invention having additional potentials connected to the bit lines FIG. 4 plots the signals on the bit lines along with the signal /PC during a read access cycle for the circuit of FIG. 3

### DETAILED DESCRIPTION OF THE EMBODIMENTS

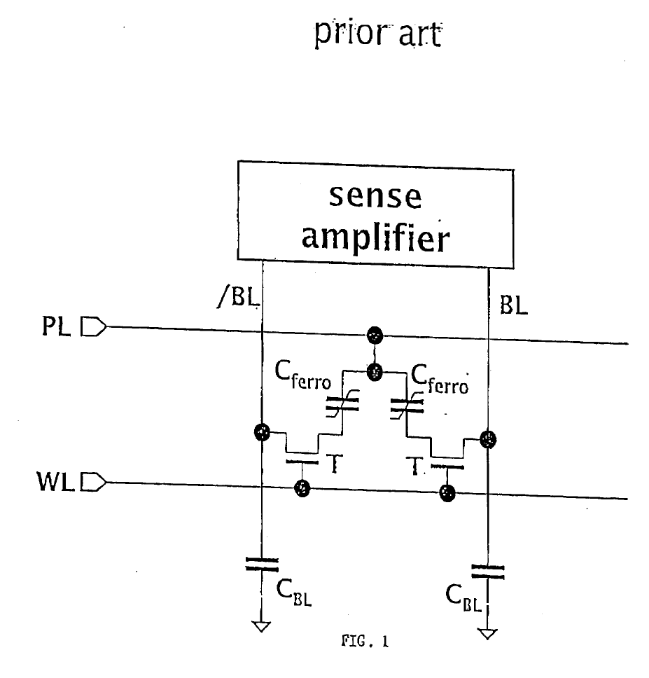

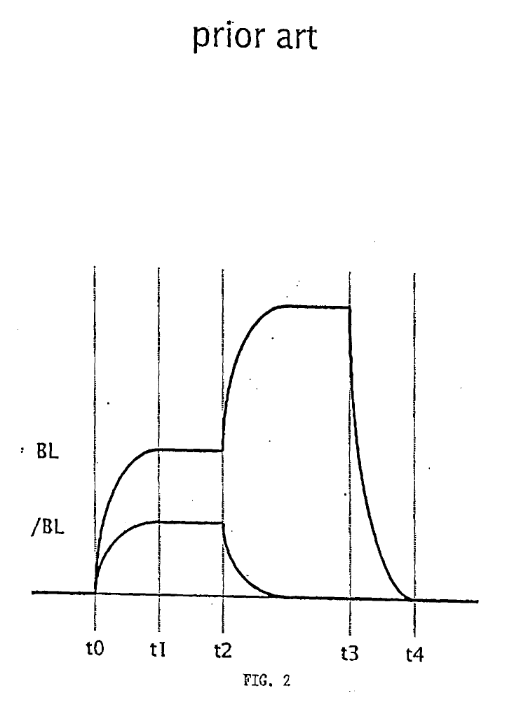

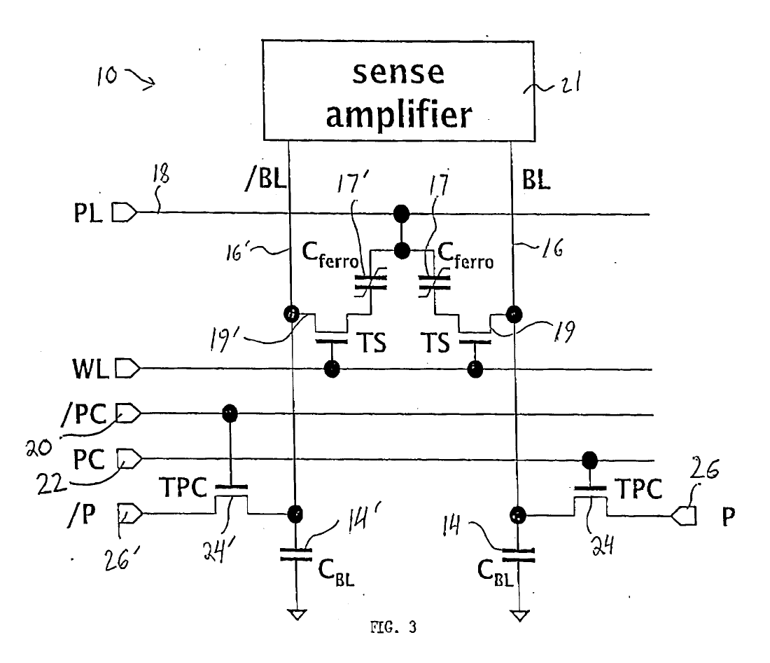

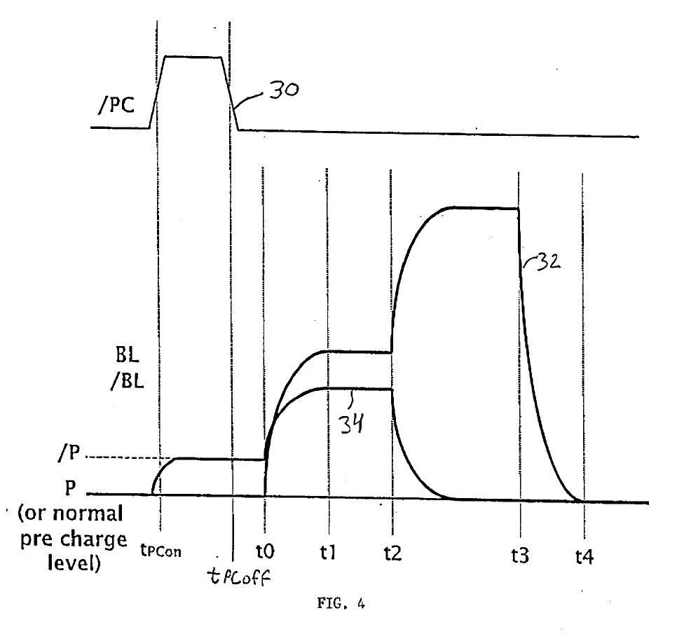

FIG. 3 shows a circuit schematic of a memory cell 10 according to the invention. The circuit of FIG. 3 differs from the prior art circuit of FIG. 1 in that potentials P 26 and /P 26′ are connected through transistors TPC 24, 24′ to bit lines BL 16 and /BL 16′ at points separated from ground by bit line capacitances 14, 14′. The potentials P 26 and /P 26′ are separately switchable for the bit lines BL 16 and /BL 16′ by the transistors TPC 24, 24′. Either, neither or both of the transistors TPC 24, 24′ can be activated by separate signals PC 22 or /PC 20 to apply the potentials P 26 and /P 26′ to the bit lines BL 16 and /BL 16′. In alternative embodiments only one of the transistors TPC 24, 24′ is in the memory cell and thus only one of the potentials P 26 and /P 26′ is applied to one of the bit lines BL 16 or /BL 16′.

The signal inputs PC 22, /PC 20 are kept at non-active (wherein the transistor TPC 24 or 24′ is off) during normal operation and the circuit is electrically similar to the circuit shown in FIG. 1. During testing, one of the signal inputs (or, in another embodiment, both of the, signal inputs) PC 22 or /PC 20 can be activated thereby applying the potentials P 26 or /P 26′ to the bit lines BL 16 or /BL 16′.

The memory cell 10 of FIG. 3 provides a test mode circuit for testing for signal margin. In order to test the memory cell 10, first data is written into the memory cell 10 and afterwards the data is read and compared to the expected (i.e. written) data. Thus, during testing it is known which line, BL 16 or /BL 16′, should have a lower and which should have a higher signal. 2T2C signal margin can be tested by selectively reducing the difference between a “0” signal on one bit line and a “1” signal on the other bit line. The bit line that is expected to have the higher signal during testing is pre-charged to a normal level as in the prior art memory cell of FIG. 1. However, the bit line which is expected to have the lower signal during testing is pre-charged to a level which is higher than the normal pre-charge level of the higher signal level bit line. The result of this test mode is a reduced differential read signal (i.e. the difference between the two bit-line signals) on the bit lines following the activation of a common plate line (PL) 18, which tightens the margin for a save operation of the chip (the worst case test condition).

The corresponding bit-line 16, 16′ signals are shown in FIG. 4. The trace 30 represents the signals /PC 20 for activating the transistor TPC 24′. The traces 32 and 34 represent the signal levels on the bit lines BL 16 and /BL 16′, respectively. In this example, the bit line /BL 16′ is assumed to be the bit line with the lower signal. The bit line BL 16 is pre-charged to a certain level (e.g. 0V in the figure) and at time tPCon the bit line test mode signal /PC 20 is activated, turning-on the transistor TPC 24′ and pre-charging the bit line /BL 16′ to a level /P which is higher than the signal level on the bit line BL 16. At time tPCoff, after two different pre-charge levels are attained on the two lines, the signal /PC 20 is deactivated, once again turning off the transistor TPC 24′ and cutting of the supply of the potential /P to the bit line /BL. There is no limitation for tPCon and tPCoff in this invention meaning that tPCoff could, in another embodiment, occur at the same time or after t0. Likewise, TPCon could occur at various times. At t0 the common plate line (PL) 18 is activated and a read signal appears on the bit lines according to the capacitance ratio Cferro/CBL. Here, Cferro is the capacitance of storage capacitors Cferro 17 and Cferro 17′ which are connected to the plate 18 on one side and to the pair of bit lines (BL 16, /BL 16′) on the other side via two select transistors (TS) 19, 19′. CBL is the capacitance of dedicated bit line capacitances (CBL) 14, 14′ connected to each bit line. At time t1 again the full read signals are developed on the two bit lines 16, 16′. At t3 the sense amplifier is deactivated and the access cycle ends at t4.

The higher signal, on /BL 16′, is therefore reduced and the difference between the higher and lower bit line signals becomes smaller for this test The amount of “signal margin” can be controlled by the time window, during which the transistor TPC 24′ is switched on, i.e. between tPCon and tPCoff.

One example of the procedure to test for the analog value of the signal margin is illustrated by the following steps;

1. Write data to and then read data from the memory cell in normal operation (without activating the transistors TSM 24 or 24′). If the differential read signal is too small, then a comparison of the read data with the write data fails, thereby indicating that the circuit has no signal margin. If the differential read signal is sufficiently large then step 2 is performed.

2. Write data to and then read data from the memory cell with the time window of the transistors 24 or 24′ set to a small value signal margin (SM0) to pre-charge the bit line /BL 16′ to a level /P which is higher than the signal level on the bit line BL 16. If the differential read signal is too small, then a comparison of the read data with the write data fails, thereby indicating that the circuit has no signal margin. If the differential read signal is sufficiently large then step 3 is performed.

3. Write data to and then read data from the memory cell with the time window of the transistors 24 or 24′ set to a slightly larger value corresponding to first signal margin (SM1) to pre-charge the bit line /BL 16′ to a level /P which is higher than the signal level on the bit line BL 16. If the differential read signal is too small, then a comparison of the read data with the write data fails, thereby indicating that the circuit has a signal margin corresponding to SM0. If the differential read signal is sufficiently large then step 4 is performed

4. Write data to and then read data from the memory cell with the time window of the transistors 24 or 24′ set to an even larger value corresponding to second signal margin (SM2) to pre-charge the bit line /BL 16′ to a level IP which is higher than the signal level on the bit line BL 16. If the differential read signal is too small, then a comparison of the read data with the write data fails, thereby indicating that the circuit has a signal margin corresponding to SM1. If the differential read signal is sufficiently large then the test is continued until the failure of the comparison.

In another embodiment, the above procedure is performed by decreasing the pre-charge of the bit line BL 16 to a level P which is lower than the signal level on the bit line /BL 16′.

In the prior art method for a read operation of a memory cell such as that shown in FIG. 1, the transistors TCP 24′, 24 of the present invention are not used and the bit lines are pre-charged to the same normal level (for example 0V or some other level) The present invention, on the other hand, includes several embodiments for producing a reduced differential read signal (i.e. the difference between the two bit-line signals) on the bit lines. For the situation when the bit line BL 16 is expected to have the higher signal and the bit line /BL 16′ is expected to have the lower signal, these embodiments include;

1. There is no transistor TPC 24, or it is not activated, but the bit line BL 16 is pre-charged to the normal level in the same way as in the normal prior-art read operation There is a transistor TPC 24′ which is activated by the signal /PC 20 and which supplies a potential /P 26′ to /BL to produce a pre-charge signal level on the bit line /BL 16′ greater than the normal level.

2. There is a transistor TPC 24 which is activated by the signal PC 22 and which supplies a potential P 26 to BL to supply a pre-charge signal P 26 having the normal signal level on the bit line BL 16. There is also a transistor TPC 24′ which is activated by the signal /PC 20 and supplies a potential /P 26′ to /BL to produce a pre-charge signal level greater than the normal pre-charge signal level on the bit line /BL 16′. 3 There is a transistor TPC 24 which is activated by the signal PC 22 and which supplies a potential P 26 to BL to produce a pre-charge signal level greater than the normal pre-charge signal level on the bit line BL 16. There is also a transistor TPC 24′ which is activated by the signal /PC 20 and which supplies a potential /P 26′ to /BL to produce a pre-charge signal level greater than the potential P 26.

4. There is a transistor TPC 24 which is activated by the signal PC 22 and which supplies a potential P 26 to BL to produce a pre-charge signal level less than the normal pre-charge signal level on the bit line BL 16. There are three alternatives for this embodiment: a) there is no transistor TPC 24′, or it is not activated, and the bit line /BL is pre-charged to the normal level in the same way as in the normal prior-art read operation; b) there is a transistor TPC 24′ which is activated by the signal /PC 20 and which supplies a potential /P 26′ to /BL to produce a pre-charge signal level approximately the same as the potential P 26; c) there is a transistor TPC 24′ which is activated by the signal /PC 20 and which supplies a potential /P 26′ to /BL to produce a pre-charge signal level less than the normal pre-charge signal level on the bit line /BL 16′ but greater than the potential P 26; and d) there is a transistor TPC 24′ which is activated by the signal /PC 20 and which supplies a potential /P 26′ to /BL to produce a pre-charge signal level greater than the potential P 26.

In alternative embodiments, the potentials /P 26′ and P 26 are generated chip internally or are provided externally.

In other embodiments, VWL and/or VPL and/or tread etc. are adjusted to overcome the difference between the voltages at the two different ferro capacitors Cferro 16, 16′ during read out. These voltage differences can arise from the two different pre-charge levels.

Thus, although the invention has been described above using particular embodiments, many variations are possible within the scope of the claims, as will be clear to a skilled reader.

We claim:

1. A semiconductor memory test mode configuration, comprising:
a first capacitor for storing digital data connecting a cell plate line to a first bit line through a first select transistor, the first select transistor activated through a connection to a word line;
a second capacitor for storing digital data connecting the cell plate line to a second bit line through a second select transistor, the second select transistor activated through a connection to the word line;
a sense amplifier connected to the first and second bit lines for measuring a differential read signal on the first and second bit lines; and
a potential connected to the first bit line through a third transistor for changing a pre-charge signal level on the first bit line when the third transistor is turned on to reduce the differential read signal.

2. The semiconductor memory test mode configuration of claim 1, wherein the first bit line has a lower read signal than the second bit line and the pre-charge signal level of the first bit line is increased by the potential so that it is greater than the pre-charge signal level of the second bit line.

3. The semiconductor memory test mode configuration of claim 1, wherein the first bit line has a higher read signal than the second bit line and the pre-charge signal level of the first bit line is reduced by the potential so that it is greater less than the pre-charge signal level of the second bit line.

4. The semiconductor memory test mode configuration of claim 1, further comprising an additional potential connected to the second bit line through a fourth transistor for changing the a pre-charge signal level on the second bit line when the fourth transistor is turned on to reduce the differential read signal.

5. The semiconductor memory test mode configuration of claim 1, wherein the potential is generated chip-internally.

6. The semiconductor memory test mode configuration of claim 1, wherein 10 the first and second select transistors are Ferroelectric Random Access Memories.

7. The semiconductor memory test mode of claim 1, wherein the first and second capacitors are ferroelectric capacitors.

8. The semiconductor memory test mode of claim 1, further comprising a bit line capacitor connected between the third transistor and ground.

9. A method for testing a semiconductor memory comprising the steps of:
identifying a first bit line that is to have a lower read signal than a second bit line;
activating a third transistor connected to the first bit line for a time interval to pre-charge the first bit line to a potential level higher than a pre-charge potential level of the second bit line;
activating a cell plate line to produce a read signal on the first and second bit lines representing digital data stored by a pair of capacitors connected to the cell plate line through first and second transistors;
activating a sense amplifier connected to the first and second bit lines thereby boosting read signals on the first and second bit lines; and
determining a reduced differential read signal on the first and second bit lines due to the increased pre-charge potential level on the first bit line.

10. The method for testing a semiconductor memory of claim 9, further comprising the step of activating a fourth transistor connected to the second bit line for a time interval to pre-charge the second bit line.

11. A method for testing a semiconductor memory comprising the steps of:
identifying a first bit line that is to have a higher read signal than a second bit line;
activating a third transistor connected to the first bit line for a time interval to pre-charge the first bit line to a potential level lower than a pre-charge potential level of the second bit line;
activating a cell plate line to produce a read signal on the first and second bit lines representing digital data stored by a pair of capacitors connected to the cell plate line through first and second transistors;
activating a sense amplifier connected to the first and second bit lines thereby boosting read signals on the first and second bit lines; and
determining a reduced differential read signal on the first and second bit lines due to the reduced pre-charge potential level on the second bit line.
